(19) United States
(12) Patent Application Publication
(10) Pub. No.: US 2005/0127522 A1
(43) Pub. Date: Jun. 16, 2005

(54) Semiconductor device and electronic device, as well as method for manufacturing the same

(76) Inventor: Hideki Yuzawa, Zida-shi (JP)

Correspondence Address: HARNESS, DICKEY & PIERCE, P.L.C., P.O. BOX 828, BLOOMFIELD HILLS, MI, 48303, US

(21) Appl. No.: 11/009,988

(22) Filed: Dec. 10, 2004

(30) Foreign Application Priority Data
Dec. 12, 2003 (JP) 2003-414829

(51) Int. Cl. H01L 23/48; H01L 21/4763

(52) U.S. Cl. 257/773; 257/776; 257/786; 438/618; 438/666

(57) ABSTRACT

A semiconductor device is provided including a substrate having a wiring pattern including a plurality of lands and a semiconductor chip having a plurality of electrodes that are mounted on the substrate so that the electrodes may be placed opposite to the lands. The plurality of lands are aligned so that they may be divided into a plurality of first groups that are placed along a plurality of first parallel lines, and form a contour spreading in a direction along the first line. The plurality of electrodes are aligned so that they may be divided into a plurality of second groups that are placed along a plurality of second parallel lines, and may form a contour spreading in a direction crossing the second line. The lands and the electrodes are electrically connected to each other by being overlapped lengthwise.

### RELATED APPLICATIONS

This application claims priority to Japanese Patent Application No. 2003-414829 filed December, 2003 which is hereby expressly incorporated by reference herein in its entirety.

### BACKGROUND

1. Field of the Invention

The present invention relates to a semiconductor device and an electronic device, as well as the method for manufacturing such devices.

2. Related Art

There is a known semiconductor device wherein a semiconductor chip is mounted on a substrate having a wiring pattern on. Further, if the reliability in connecting a wiring pattern with an electrode of a semiconductor chip can be enhanced, the reliability of a semiconductor device can be enhanced.

The present invention aims to provide a semiconductor device and an electronic device that have a high reliability, as well as a method for manufacturing such devices.

### SUMMARY

(1) A semiconductor device according to the present invention comprises a substrate having a wiring pattern including a plurality of lands and a semiconductor chip having a plurality of electrodes that are mounted on the substrate so that the electrodes may be placed opposite to the lands.

Further, the plurality of lands are aligned so as to be divided into a plurality of first groups that are placed respectively along a plurality of first parallel lines, and form a contour spreading along the first line.

Furthermore, the wiring pattern includes a plurality of wires that are drawn out from the plurality of lands and stretches in a direction crossing the first line.

Also, the plurality of electrodes are aligned so as to be divided into a plurality of second groups that are placed respectively along a plurality of second parallel lines, and form a contour spreading in a direction crossing the second line.

In addition, the plurality of lands and the plurality of electrodes respectively overlap each other, crossing lengthwise, whereby electricallyconnected According to the present invention, the land and the electrode overlap each other so that they may cross lengthwise. By crossing the land and the electrode lengthwise, the oppositeness between the land and the electrode can be maintained even if a positional shift occurs between a semiconductor chip and a substrate after mounting the former on the latter. Therefore, a highly reliable semiconductor device having a stabilized electric connecting between the land and the electrode can be provided.

(2) In the above semiconductor device, the plurality of electrodes can be aligned so as to be divided into a plurality of third groups that are placed respectively along a plurality of third lines stretching in a direction crossing the second line.

(3) In the above semiconductor device, the third line can stretch in a direction orthogonal to the second line.

(4) In the above semiconductor device, the third line can stretch in a direction oblique to the second line.

(5) In the above semiconductor device, adjacent two of the third lines can stretch in parallel.

(6) In the above semiconductor device, adjacent two of the third lines can be in linear symmetry with a line perpendicular to the second line as an axis of symmetry.

(7) In the above semiconductor device, the plurality of lands can be aligned so as to be divided into a plurality of fourth groups placed respectively along a plurality of fourth lines stretching in a direction crossing the first line.

(8) In the above semiconductor device, a group of the wires that are drawn out respectively from the lands of the same fourth group can be drawn out from the same side of the two sides, of the lands of the same forth group, along the first line.

(9) In the above semiconductor device, the lands of the same fourth group can protrude, with different lengths, on the same side of the two sides along the first line, and further the protrusions can be formed so that their length may become longer in the order aligned along any of the fourth lines.

(10) In the above semiconductor device, the group of wires that are drawn out respectively from the lands of the same fourth group can be configured so that, next to one of the wires connected to one of the lands, a first land, and at the same time on the side where the first land is protruding, another one of the wires connected to another one of the lands, a second land, that has a protrusion length next longest to that of the first land may be configured.

(11) An electronic device according to the present invention comprises a first substrate having a first wiring pattern including a plurality of first lands and a second substrate having a second wiring pattern including a plurality of second lands.

Further, the plurality of first lands are aligned so as to be divided into a plurality of first groups that are placed respectively along a plurality of first parallel lines, and form a contour spreading in a direction along the first line.

Furthermore, the first wiring pattern includes first wires that are drawn out from the plurality of first lands and respectively stretch in a direction crossing the first line.

Also, the plurality of second lands are aligned so as to be divided into a plurality of second groups that are placed respectively along a plurality of second parallel lines, and form a contour spreading in a direction crossing the second line.

In addition, the second wiring pattern includes second wires that are drawn out from the plurality of second lands and stretch respectively in a direction crossing the second line.

Moreover, the plurality of first lands and the plurality of second lands are respectively placed opposite to each other, crossing lengthwise, whereby electrically connected. According to the present invention, the first land and the second land overlap each other so that they may cross lengthwise. By crossing the first land and the second land lengthwise, the oppositeness between the first land and the second land can be maintained. Therefore, a highly reliable electronic device having a stabilized electric connecting between the first land and the second land can be provided.

(12) In the above electronic device, the plurality of second lands can be aligned so as to be divided into a plurality of third groups that are placed respectively along a plurality of third lines stretching in a direction crossing the second line.

(13) In the above electronic device, the third line can stretch in a direction oblique to the second line.

(14) In the above electronic device, adjacent two of the third lines can stretch in parallel.

(15) In the above electronic device, adjacent two of the third lines can be in linear symmetry with a line perpendicular to the second line as an axis of symmetry.

(16) In the above electronic device, the plurality of first lands can be aligned so as to be divided into a plurality of fourth groups placed respectively along a plurality of fourth lines stretching in a direction crossing the first line.

(17) In the above electronic device, a group of the wires that are drawn out respectively from the first lands of the same fourth group can be drawn out from the same side of the two sides, of the first lands of the same forth group, along the first line.

(18) A method for manufacturing a semiconductor device according to the present invention comprises the following steps: mounting a semiconductor chip, having a plurality of electrodes, on a substrate, having a wiring pattern including a plurality of lands, so that the electrodes and the lands may be placed opposite to each other, for the purpose of electrically connecting the electrodes and the lands; aligning the plurality of lands so that they may be divided into a plurality of first groups that are placed respectively along a plurality of first parallel lines, and may form a contour stretching along the first line; configuring the wiring pattern including a plurality of wires that are drawn out from the plurality of lands and stretch respectively in a direction crossing the first line; aligning the plurality of electrodes so that they may be divided into a plurality of second groups that are placed respectively along a plurality of second parallel lines, and may form a contour spreading in a direction crossing the second line; and overlapping the plurality of lands and the plurality of electrodes so that they may respectively cross each other lengthwise. According to the present invention, the land and the electrode are overlapped each other so that they may cross lengthwise.

By crossing the land and the electrode lengthwise, the electrode can be contacted with the corresponding land even if the positioning between the substrate and the semiconductor chip is not precise enough. Therefore, it is possible to manufacture a semiconductor device without performing a precise positioning, and also to manufacture a highly reliable semiconductor device with a high efficiency.

(19) In the above method for manufacturing a semiconductor device, the plurality of electrodes can be aligned so as to be divided into a plurality of third groups that are placed respectively along a plurality of third lines stretching in a direction crossing the second line.
(20) In the above method for manufacturing a semiconductor device, the third line can stretch in a direction orthogonal to the second line.

(21) In the above method for manufacturing a semiconductor device, the third line can stretch in a direction oblique to the second line.

(22) In the above method for manufacturing a semiconductor device, adjacent two of the third lines can stretch in parallel.

(23) In the above method for manufacturing a semiconductor device, adjacent two of the third lines can be in linear symmetry with a line perpendicular to the second line as an axis of symmetry.

(24) In the above method for manufacturing a semiconductor device, the plurality of lands can be aligned so as to be divided into a plurality of fourth groups that are placed respectively along a plurality of fourth lines stretching in a direction crossing the first line.

(25) In the above method for manufacturing a semiconductor device, a group of the wires that are drawn out respectively from the lands of the same fourth group can be drawn out from the same side of the two sides, of the lands of the same forth group, along the first line.

(26) In the above method for manufacturing a semiconductor device, the lands of the same fourth group can protrude, with different lengths, on the same side of the two sides along the first line, and further the protrusions can be formed so that their length may become longer in the order aligned along any of the fourth lines.

(27) In the above method for manufacturing a semiconductor device, the group of wires that are drawn out respectively from the lands of the same fourth group can be configured so that, next to one of the wires connected to one of the lands, a first land, and at the same time on the side where the first land is protruding, another one of the wires connected to another one of the lands, a second land, that has a protrusion length next longest to that of the first land may be configured.

(28) A method for manufacturing an electronic device according to the present invention comprises the following steps: placing a plurality of first lands of a first wiring pattern, provided on a first substrate, opposite to a plurality of second lands of a second wiring pattern, provided on a second substrate, for the purpose of electrically connecting them; aligning the plurality of first lands so that they may be divided into a plurality of first groups that are placed respectively along a plurality of first parallel lines, and may form a contour spreading along the first line; configuring the first wiring pattern including first wires that are drawn out from the plurality of first lands and stretch respectively in a direction crossing the first line; aligning the plurality of second lands so that they may be divided into a plurality of second groups that are placed respectively along a plurality of second parallel lines, and may a contour spreading in a direction crossing the second line; configuring the second wiring pattern including second wires that are drawn out from the plurality of second lands and stretch respectively in a direction crossing the second line; and overlapping the plurality of first lands and the plurality of second lands so that they may respectively cross each other lengthwise.

According to the present invention, the first land and the second land are overlapped each other so that they may respectively cross lengthwise. By crossing the first land and the second land lengthwise, the corresponding lands can be contacted with each other even if the positioning between the first substrate and the second substrate is not precise enough. Therefore, it is possible to manufacture an electronic device without performing a precise positioning, and also to manufacture a highly reliable electronic device with a high efficiency.

(29) In the above method for manufacturing an electronic device, the plurality of second lands can be aligned so as to be divided into a plurality of third groups that are placed respectively along a plurality of third lines stretching in a direction crossing the second line.

(30) In the above method for manufacturing an electronic device, the third line can stretch in a direction oblique to the second line.

(31) In the above method for manufacturing an electronic device, adjacent two of the third lines can stretch in parallel.

(32) In the above method for manufacturing an electronic device, adjacent two of the third lines can be in linear symmetry with a line perpendicular to the second line as an axis of symmetry.

(33) In the above method for manufacturing an electronic device, the plurality of first lands can be aligned so as to be divided into a plurality of fourth groups that are placed respectively along a plurality of fourth lines stretching in a direction crossing the first line.

(34) In the above method for manufacturing an electronic device, a group of the first wires that are drawn out respectively from the first lands of the same fourth group can be drawn out from the same side of the two sides, of the first lands of the same forth group, along the first line.

### BRIEF DESCRIPTION OF THE DRAWINGS

FIG. 1 is a drawing for describing a semiconductor device according to the embodiment of the present invention.

FIG. 2 is a drawing for describing a semiconductor device according to the embodiment of the present invention.

FIG. 3A and FIG. 3B are drawings for describing a semiconductor device according to the embodiment of the present invention.

FIG. 4 is a drawing for describing a display device having a semiconductor device according to the embodiment of the present invention.

FIG. 5 is a drawing of an electronic apparatus having a semiconductor device according to the embodiment of the present invention.

FIG. 6 is a drawing of an electronic apparatus having a semiconductor device according to the embodiment of the present invention.

FIG. 7 is a drawing for describing a semiconductor device according to a variant of the embodiment of the present invention.

FIG. 8 is a drawing for describing a semiconductor device according to a variant of the embodiment of the present invention.

FIG. 9 is a drawing for describing a semiconductor device according to a variant of the embodiment of the present invention.

FIG. 10 is a drawing for describing a semiconductor device according to a variant of the embodiment of the present invention.

FIG. 11 is a drawing for describing a semiconductor device according to a variant of the embodiment of the present invention.

FIG. 12 is a drawing for describing a semiconductor device according to a variant of the embodiment of the present invention.

FIG. 13 is a drawing for describing a semiconductor device according to a variant of the embodiment of the present invention.

FIG. 14 is a drawing for describing a semiconductor device according to a variant of the embodiment of the present invention.

FIG. 15 is a drawing for describing a semiconductor device according to a variant of the embodiment of the present invention.

FIG. 16 is a drawing for describing a semiconductor device according to a variant of the embodiment of the present invention.

FIG. 17 is a drawing for describing an electronic device according to the embodiment of the present invention.

FIG. 18 is a drawing for describing an electronic device according to the embodiment of the present invention.

FIG. 19 is a drawing for describing an electronic device according to the embodiment of the present invention.

FIG. 20 is a drawing for describing an electronic device according to a variant of the embodiment of the present invention.

FIG. 21 is a drawing for describing an electronic device according to a variant of the embodiment of the present invention.

FIG. 22 is a drawing for describing an electronic device according to a variant of the embodiment of the present invention.

FIG. 23 is a drawing for describing an electronic device according to a variant of the embodiment of the present invention.

### DETAILED DESCRIPTION

Embodiments of the present invention will now be described in detail referring to the accompanying drawings. However, the present invention is not limited to the following embodiments.

Semiconductor Device

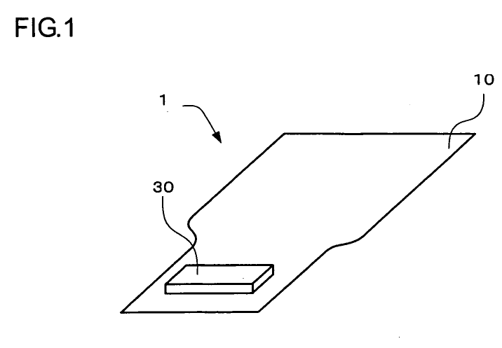

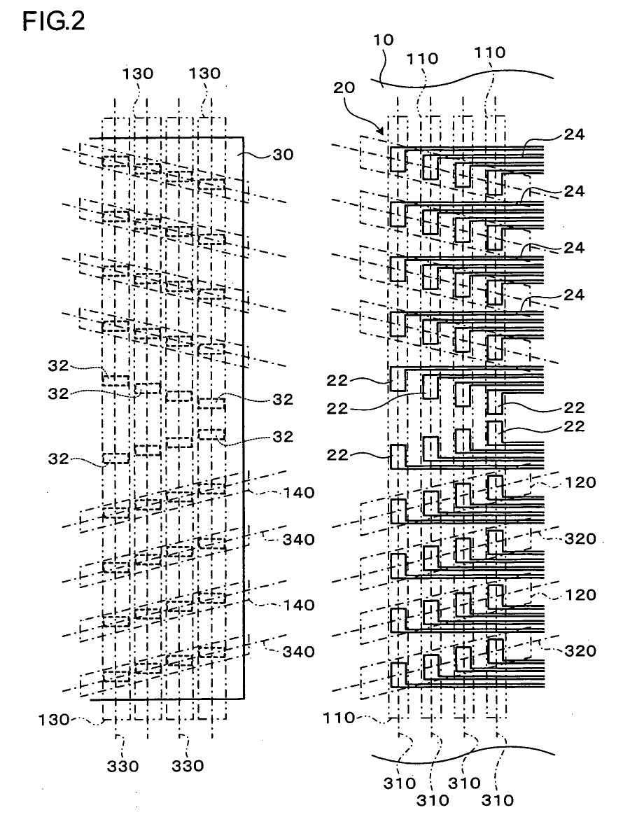

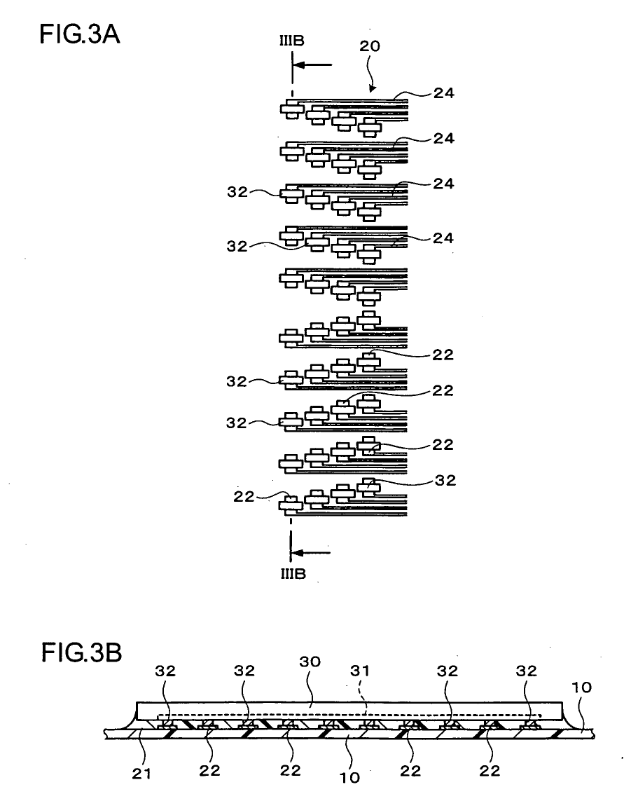

FIGS. 1 through 3B are drawings for describing a semiconductor device according to the embodiment of the present invention. Further, FIG. 1 is a schematic drawing of a semiconductor device 1 according to the embodiment of the present invention. Furthermore, FIG. 2 is a drawing of the semiconductor 1 separated into a substrate 10 and a semiconductor chip 30. FIG. 3A and FIG. 3B are enlarged views of part of the semiconductor device 1. In FIG. 3A, the substrate 10 and the semiconductor chip 30 are omitted for the sake of describing the connecting state of a land 22 and an electrode 32. In addition, FIG. 3B is a view of FIG. 3A along a IIIB-to-IIIB line.

The semiconductor device according to the present embodiment has the substrate 10. As the material of the substrate 10, which is not especially specified, organic materials (for example, an epoxy substrate), inorganic materials (for example, a ceramic substrate and a glass substrate), or combinations of such materials (for example, a glass epoxy substrate) can be employed. The substrate 10 can be either a rigid substrate or a flexible substrate, such as a polyester substrate or a polyimide substrate (refer to FIG. 1). The substrate 10 can be a substrate for chip on film (COF). Also, the substrate 10 can be a single-layer substrate comprising one layer or a laminated substrate comprising a plurality of laminated layers. Further, the shape and thickness of the substrate 10 is not especially specified.

The substrate 10 has a wiring pattern 20 which comprises a plurality of lands 22. The wiring pattern 20 can be formed with one or more layers of any of the following: copper (Cu), chromium (Cr), titanium (Ti), nickel (Ni), titanium-tungsten (Ti—W), gold (Au), aluminum (Al), nickel-vanadium (NiV) and tungsten (W). When a laminated substrate is prepared as the substrate 10, the wiring pattern 20 can be provided between respective layers. Further, when a glass substrate is used as the substrate 10, the wiring pattern 20 can be formed of a metal film such as indium tin oxide (ITO), Cr, Al, etc., a metal compound film or a composite film of such materials. The method for forming the wiring pattern 20 is not especially specified. For example, the wiring pattern 20 can be formed by means of sputtering, etc. Also, the additive method, in which the wiring pattern 20 is formed by means of electroless plating, can be employed. In addition, the wiring pattern 20 can be plated with solder, tin, gold, nickel, etc.

As shown in FIG. 2, the plurality of lands 22 are aligned so as to be divided into a plurality of first groups 110 placed respectively along a plurality of first parallel lines 310. Further, the plurality of lands 22 respectively form a contour spreading along the first lines 310. As shown in FIG. 2, the plurality of lands 22 can also be aligned so as to be divided into a plurality of fourth groups 120 placed respectively along a plurality of fourth lines 320 stretching in a direction crossing the first line 310, where adjacent two of the fourth lines 320 can stretch in parallel. In addition, the wiring pattern 20 comprises wires 24, which are drawn out from the lands, stretching respectively in a direction crossing the first line 310. As shown in FIG. 2, when the lands 22 are aligned so as to be divided into the plurality of fourth groups 120, a group of wires 24, which are drawn out respectively from the lands 22 of the same fourth group 120, can be drawn out from the same side of the two sides, of the lands 22 of the same fourth group, along the first line 310.

The semiconductor device according to the present embodiment has the semiconductor chip 30 (refer to FIG. 1). The semiconductor chip 30 has a plurality of electrodes 32. As shown in FIG. 2, the plurality of electrodes 32 are aligned so as to be divided into a plurality of second group 130 that are placed respectively along a plurality of second parallel lines 330. Further, the electrodes 32 respectively form a contour spreading in a direction crossing the second line 330. As shown in FIG. 2, the plurality of electrodes 32 can also be aligned so as to be divided into a plurality of third groups 140 that are placed respectively along a plurality of third lines 340 stretching in a direction crossing the second line 330. Further, the plurality of third lines 340 can stretch in a direction oblique to the second line 330, and adjacent two of the third lines 340 can stretch in parallel (refer to FIG. 2). In addition, the electrodes 32 can be aligned along two parallel sides (or four sides), near the edges, of the active surface of the semiconductor chip 30. Alternatively, the electrodes 32 can be provided on the entire active surface of the semiconductor chip 30, in the shape of area arrays. Further, the semiconductor chip 30 can have an integrated circuit 31 that comprises a transistor, a memory device, etc. (refer to FIG. 3B). Furthermore, the electrode 32 can be electrically connected to the inner part of the semiconductor chip 30. The electrode 32 can also be electrically connected to the integrated circuit 31. Possibly, the electrodes 32 can be called an electrode 32, including electrodes not electrically connected to the integrated circuit 31. The electrode 32 can include, for example, a pad and bumps formed on the pad (not illustrated).

The semiconductor chip 30 is mounted on the substrate 10 (refer to FIG. 1 and FIG. 3B). The semiconductor chip 30 is mounted so that the electrode 32 may be placed opposite to the land 22 (refer to FIG. 3B). Further, as shown in FIG. 3A, the land 22 and the electrode 32 are electrically connected to each other by being overlapped so that they may cross lengthwise. By overlapping the land 22 and the electrode 32 lengthwise, the oppositeness between the land 22 and the electrode 32 can be maintained even if a positional shift occurs between the semiconductor chip 30 and the substrate 10 after mounting the former on the latter. Therefore, a highly reliable semiconductor device having a stabilized electric connecting between the land 22 and the electrode 32 can be provided. In addition, the electrical connecting between the land 22 and the electrode 32 can be achieved by contacting them. In another case, the land 22 and the electrode 32 can be electrically connected to each other with an intermediary of a conductive particle between them (not illustrated). In another case, the land 22 and the electrode 32 can be electrically connected by means of alloy junction (for example, Au-to-Au or Au-to-Sn junction). Further, as shown in FIG. 3B, the semiconductor device 1 can have a reinforcement 21 for bonding the substrate 10 and the semiconductor chip 30. The material of the reinforcement 21 is not limited to but can be resin. With the reinforcement 21, the reliability of the semiconductor device can be enhanced.

The semiconductor device according to the present embodiment is configured as described above. Now, a method for manufacturing the same device will be described.

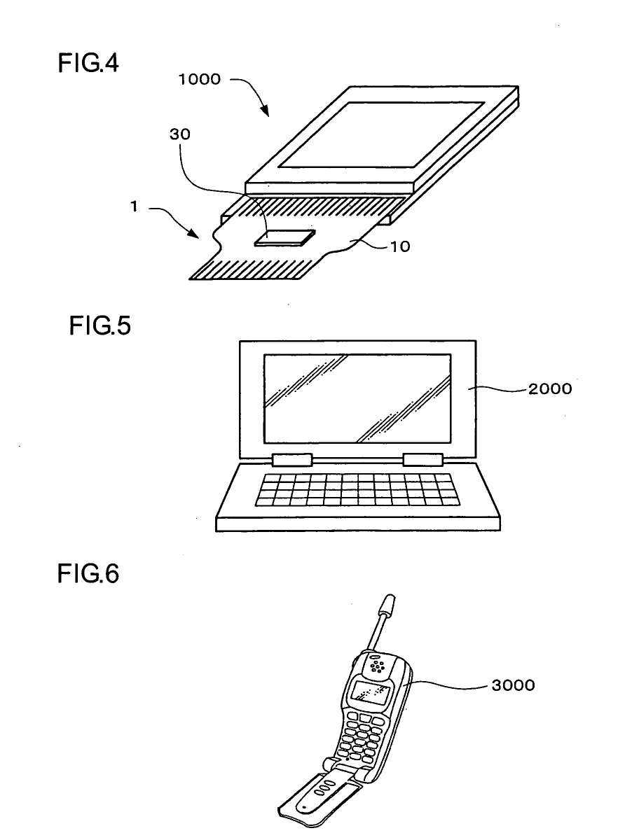

The method for manufacturing the semiconductor device according to the present embodiment comprises mounting the semiconductor chip 30, having the plurality of electrodes 32, on the substrate 10, having the wiring pattern 20 including the plurality of lands 22, so that the electrodes 32 and the lands 22 may be placed opposite to each other, for the purpose of electrically connecting the electrodes 32 and the lands 22. As described above, the land 22 takes a contour spreading along the first line 310. Also, the electrode 32 takes a contour spreading in a direction crossing the second line 330. Further, in the method for manufacturing a semiconductor device according to the present embodiment, the land 22 and the electrode 32 are overlapped each other lengthwise. Thus, the positioning between the substrate 10 and the semiconductor chip 30 is made easier. More specifically, by crossing the land 22 and the electrode 32 lengthwise, the electrode 32 can be contacted with the corresponding land 22 even if the positioning between the two is not precise enough. Therefore, it is possible to manufacture a semiconductor device without performing a precise positioning, and also to manufacture a highly reliable semiconductor device with a high efficiency. In addition, for the electrical connecting between the land 22 and the electrode 32, any of the following publicly known methods can be employed: dielectric resin junction (for example, junction using NCP or NCF), anisotropic conductive material junction (for example, junction using ACF or ACP), metal junction (for example, Au-to-Au or Au-to-Sn junction), soldered junction, etc. Further, the semiconductor device 1 can be manufactured including a process of forming the reinforcement 21 for bonding the substrate 10 and the semiconductor chip 30 (refer to FIG. 1). Besides, FIG. 4 shows a display device 1000 having the semiconductor device 1. The display device 1000 can be, for example, a liquid crystal display device or an electrical luminescence (EL) display device. Further, as electronic apparatus having the semiconductor device 1, FIG. 5 and FIG. 6 show a notebook personal computer 2000 and a cellular phone 3000, respectively.

Variants

The present invention, which is not limited to the above embodiment, can be modified variously. Now, variants of a semiconductor device according to the embodiment of the present invention will now be described in detail. In addition, for the variants below, the descriptions given above will be applied as far as possible.

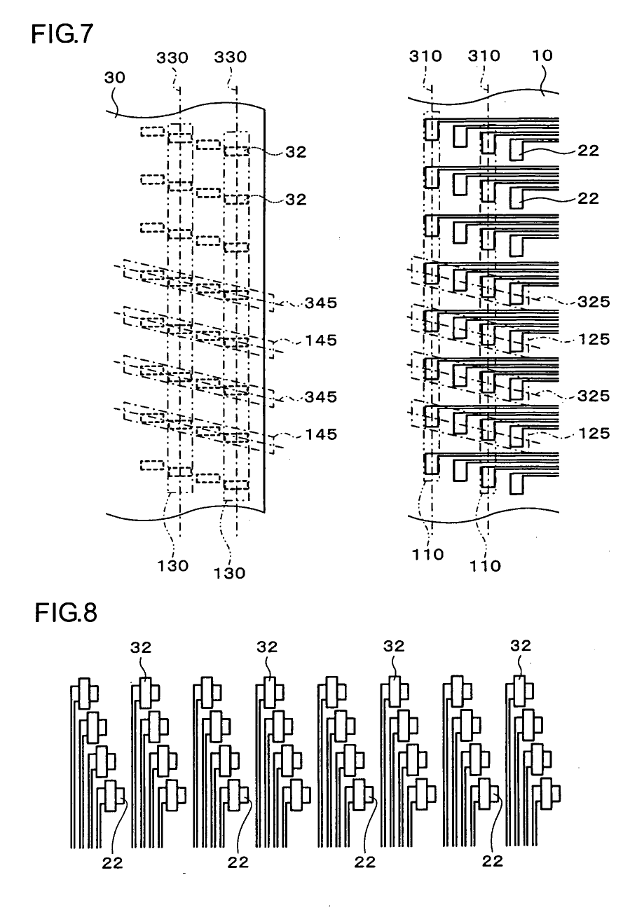

In a variant shown in FIG. 7 and FIG. 8, the plurality of electrodes 32 are aligned so as to be divided into a plurality of third groups 145 that are placed respectively along a plurality of third lines 345 stretching in a direction crossing the second line 330. The plurality of third lines 345 stretch in a direction oblique to the second line 330. Further, as shown in FIG. 7, the plurality of third lines 345 stretch respectively in parallel. That is, all of the third lines 345 can stretch in parallel. Here, the lands 22 can be aligned so as to be divided into a plurality of fourth groups 125 that are placed respectively along a plurality of fourth lines 325 stretching in a direction crossing the first line 310, and the plurality of fourth lines 325 can stretch respectively in parallel. Further, as shown in FIG. 8, the land 22 and the electrode 32 are electrically connected to each other by being overlapped lengthwise.

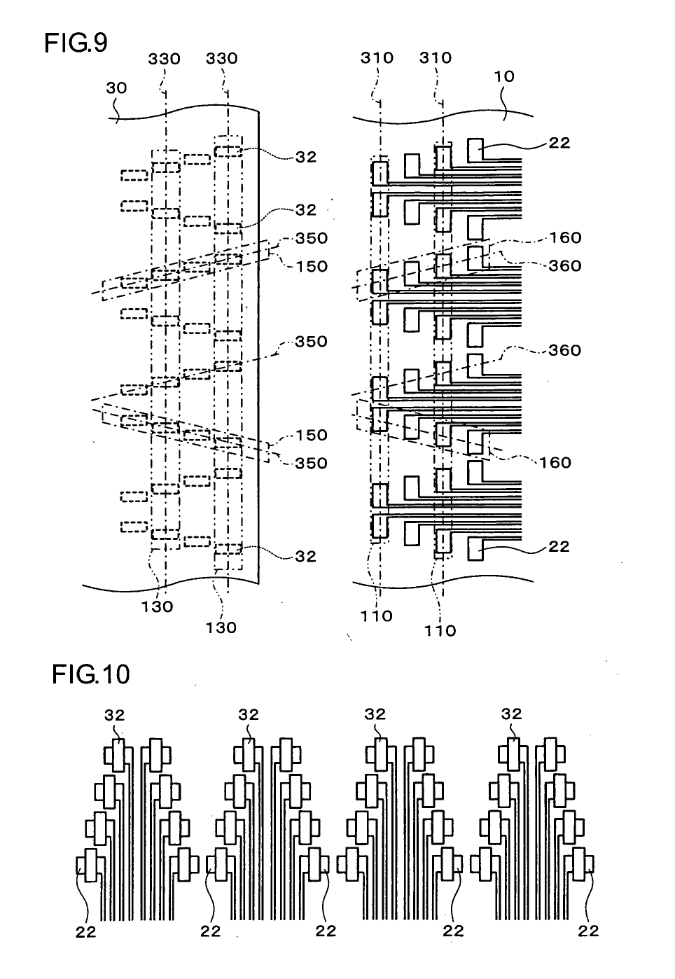

In a variant shown in FIG. 9 and FIG. 10, the plurality of electrodes 32 are aligned so as to be divided into a plurality of third groups 150 that are placed respectively along a plurality of third lines 350. The third lines 350 stretch in a direction crossing the second line 330, and adjacent two of the third lines 350 are in linear symmetry with a line perpendicular to the second line 330 as an axis of symmetry. Here, the lands 22 can be aligned so as to be divided into a plurality of fourth groups 160 that are placed respectively along a plurality of fourth lines 360 stretching in a direction crossing the first line 310, and adjacent two of the fourth lines 360 can be in linear symmetry with a line perpendicular to the first line 310 as an axis of symmetry. Further, as shown in FIG. 10, the land 22 and the electrode 32 are electrically connected to each other by being overlapped lengthwise.

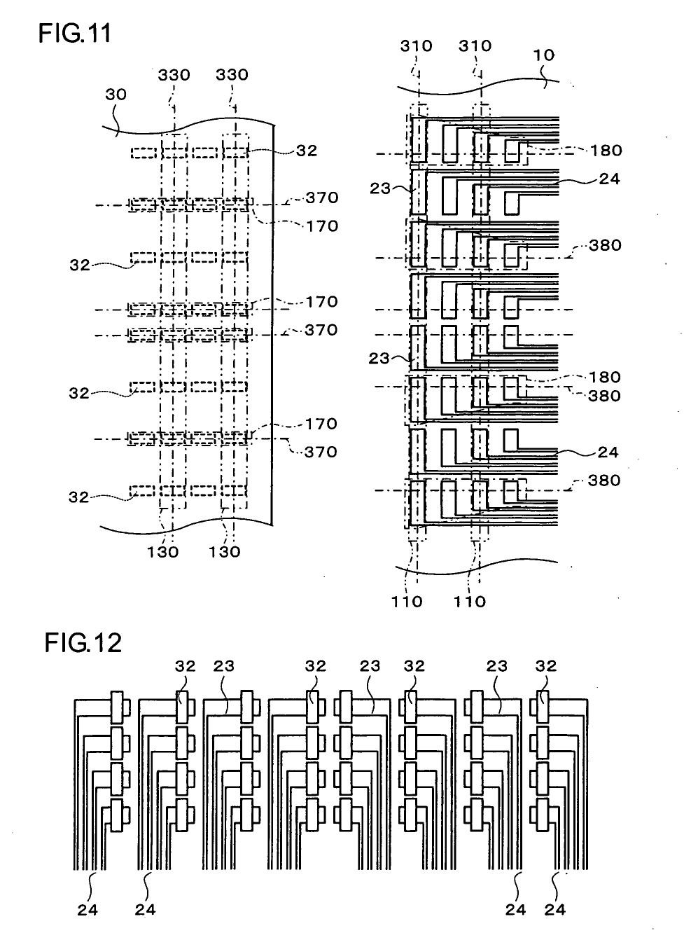

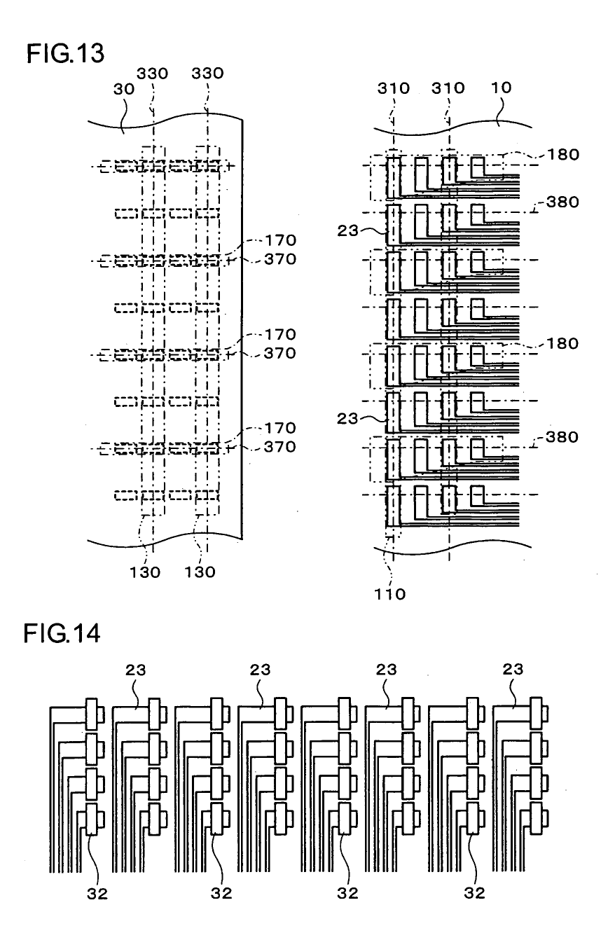

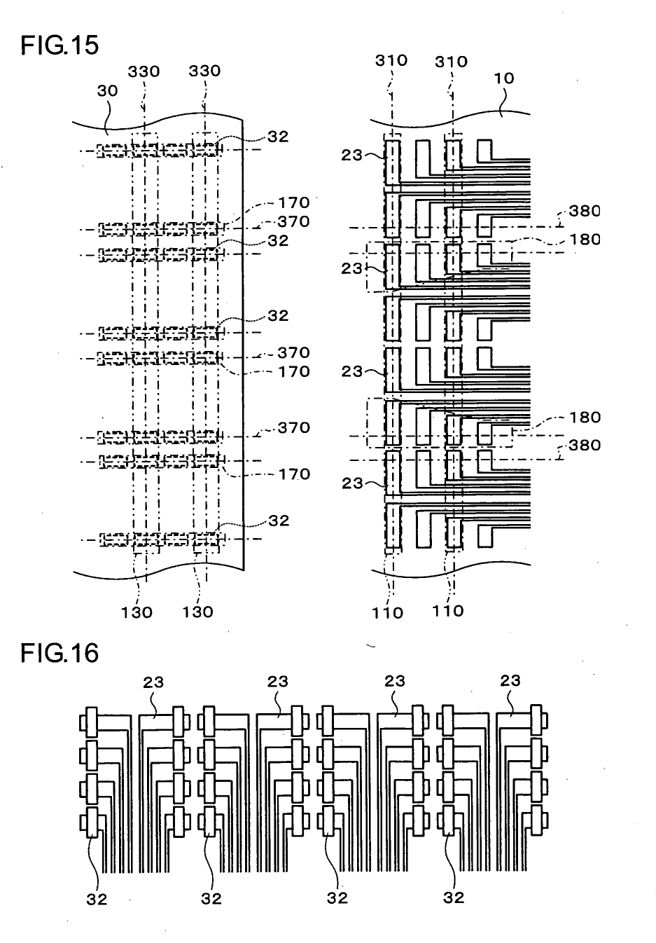

In a variant shown in FIG. 11 and FIG. 12, the plurality of electrodes 32 are aligned so as to be divided into a plurality of third groups 170 that are placed respectively along a plurality of third lines 370. Further, as shown in FIG. 11, the third line 370 stretch in a direction orthogonal to the second line 330. Here, a plurality of lands 23 can be aligned so as to be divided into a plurality of fourth groups 180 that are placed respectively along a plurality of fourth lines 380. As shown in FIG. 11, the fourth line 380 can stretch in a direction orthogonal to the first line 310. Further, the lands 23 of the same fourth group 180 can protrude, with different lengths, on the same side of the two sides along the first line 310. In addition, the protrusions can be formed so that their length may become longer in the order aligned along any of the fourth lines 380. Here, a group of the wires 24 that are drawn out respectively from the lands 23 of the same fourth group 180 can be drawn out from the same side of the two sides, of the lands 23 of the same forth group 180, along the first line 310. As shown in FIG. 11, each wire 24 can be drawn out from one of the sides, of the land 23, along the first line 310 and at the same time from the side where the land 23 is protruding. The lands 23 of adjacent two of the fourth groups 180 can protrude on the same side of the two sides along the first line 310. As shown in FIG. 11, the plurality of fourth groups 180 can comprise a group which includes lands protruding on one side of the two sides along the first line 310 and a group which includes lands protruding on the other side. Further, the group of wires 24 that are drawn out respectively from the lands 23 of the same fourth group 180 can be configured so that, next to one of the wires connected to one of the lands, a first land, and at the same time on the side where the first land is protruding, another one of the wires connected to another one of the lands, a second land, that has a protrusion length next longest to that of the first land may be configured. In addition, as shown in FIG. 12, the land 23 and the electrode 32 are electrically connected to each other by being overlapped lengthwise. Furthermore, in the present variant, the lands 23 of all the fourth groups 180 can protrude on the same side of the two sides along the first line 310, as shown in FIG. 13. FIG. 14 is a drawing of the connecting under such a state between the land 23 and the electrode 32. Alternatively, as shown in FIG. 15, the lands 23 of adjacent two of the fourth groups 180 can protrude respectively on the opposite side along the first line 310. FIG. 16 is a drawing of the connecting under such a state between the land 23 and the electrode 32.

With the above variants, an effect equivalent to that of the above embodiment can be achieved. In addition, for other configurations, any of the descriptions given above can be applied.

Electronic Device

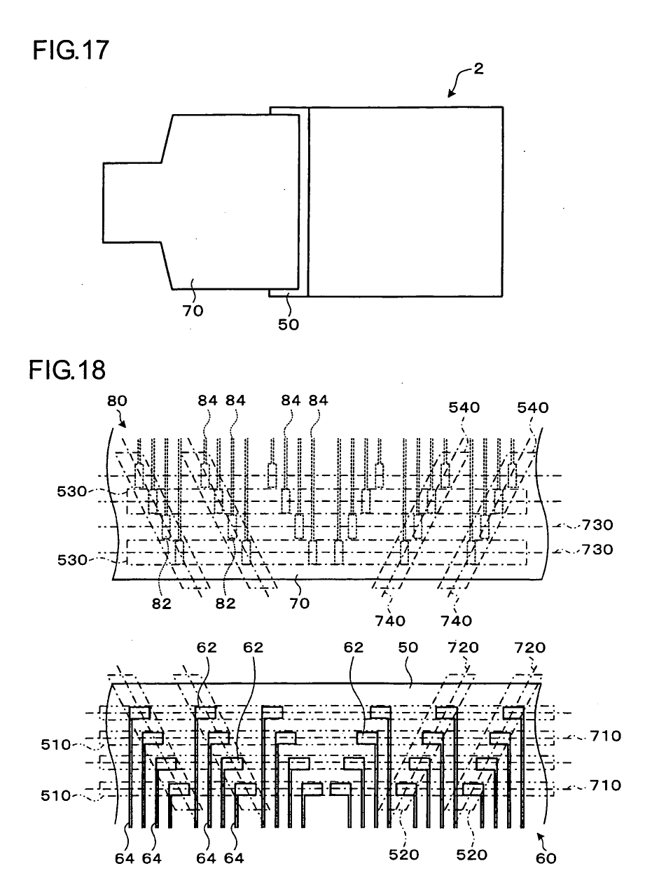

FIG. 17 to FIG. 19 are drawings for describing an electronic device according to the embodiment of the present invention. In addition, for electronic devices to be described below, the descriptions given above will be applied as far as possible.

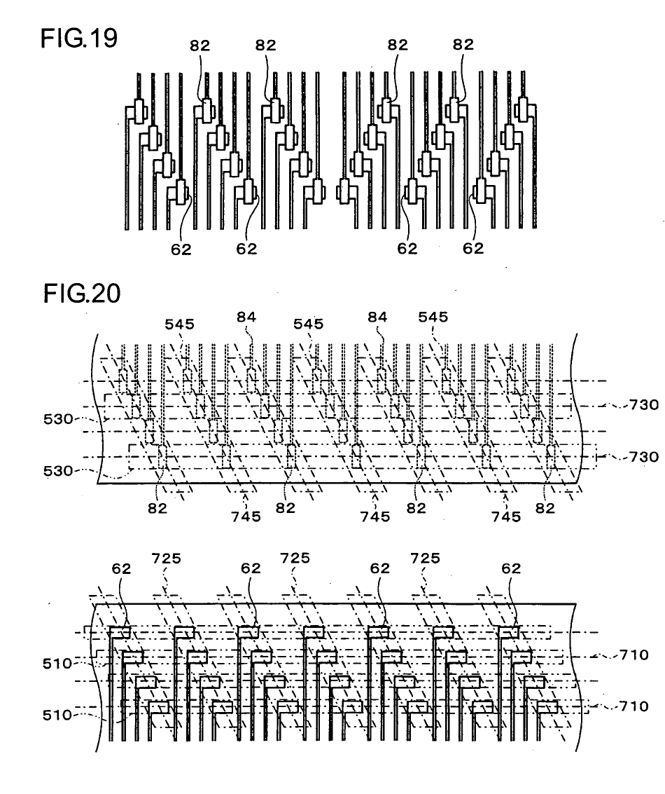

FIG. 17 is a schematic drawing of an electronic device 2 according to the embodiment of the present invention. Further, FIG. 18 is a drawing of the electronic device 2 separated into a first substrate 50 and a second substrate 70. Also, FIG. 19 is a drawing for describing the connecting state between a first land 62 and a second land 82.

The electronic device according to the present embodiment comprises the first substrate 50 and the second substrate 70. The first substrate 50 can be a glass substrate, for example. The first substrate 50 can be part of an electrical engineering panel (a liquid crystal panel, electroluminescence panel, etc.). In addition, the second substrate 70 can be a flexible substrate or film, for example. However, the first and the second substrates 50 and 70 are not limited to such materials. For example, a flexible substrate, etc. can be used as the first substrate, and a glass substrate can be used as the second substrate.

As shown in FIG. 18, the first substrate 50 comprises a first wiring pattern 60. The first wiring pattern 60 comprises a plurality of first lands 62. The plurality of first lands 62 are aligned so as to be divided into a plurality of first groups 510 that are placed respectively along a plurality of first parallel lines 710. Further, each of the first lands 62 takes a contour spreading in a direction along the first line 710. As shown in FIG. 18, the plurality of first lands 62 can be aligned so as to be divided into a plurality of fourth groups 520 that are placed respectively along a plurality of fourth lines 720 stretching in a direction crossing the first line 710. The fourth line 720 can stretch in a direction oblique to the first line 710, where adjacent two of the fourth lines 720 can stretch in parallel (refer to FIG. 18). Further, the first wiring pattern 60 comprises first wires 64 that are respectively drawn out from the first lands 62 and stretch in a direction crossing the first line 710. As shown in FIG. 18, when the first lands 62 are aligned so as to be divided into the plurality of fourth groups 520, a group of the first wires 64 that are drawn out respectively from the first lands 62 of the same fourth group 520 can be drawn out from the same side of the two sides, of the first lands 62 of the same fourth group 520, along the first line 710.

As shown in FIG. 18, the second substrate 70 comprises a second wiring pattern 80. The second wiring pattern 80 comprises a plurality of second lands 82. The plurality of second lands 82 are aligned so as to be divided into a plurality of second groups 530 that are placed respectively along a plurality of second parallel lines 730. Further, each of the second lands 82 takes a contour spreading in a direction crossing the second line 730. As shown in FIG. 18, the plurality of second lands 82 can be aligned so as to be divided into a plurality of third groups 540 that are placed respectively along a plurality of third lines 740 stretching in a direction crossing the second line 730. The third line 740 can stretch in a direction oblique to the second line 730, where adjacent two of the third lines 740 can stretch in parallel as shown in FIG. 18. Further, the second wiring pattern 80 comprises second wires 84 that are respectively drawn out from the second lands 82 and stretch in a direction crossing the second line 730.

In the electronic device according to the present embodiment, as shown in FIG. 19, the first land 62 and the second land 82 are placed opposite to each other so that they may overlap lengthwise and whereby electrically connected. By placing the first land 62 opposite to the second land 82 lengthwise, a highly reliable electronic device having a stabilized electric connecting between the first and the second lands 62 and 82 can be provided.

The electronic device according to the present embodiment is configured as described above. Now, a method for manufacturing the same device will be described.

The method for manufacturing the electronic device according to the present embodiment comprises placing the plurality of first lands 62 of the first wiring pattern 60 provided on the first substrate 50 opposite to the plurality of second lands 82 of the second wiring pattern 80 provided on the second substrate 70, for the purpose of electrically connecting them. As described above, the first land 62 takes a contour spreading in a direction along the first line 710. Further the second land 82 takes a contour spreading in a direction crossing the second line 730. In addition, in the method for manufacturing the electronic device according to the present embodiment, the first and the second land 62 and 82 are overlapped each other, crossing lengthwise. Thus, positioning of the first and the second substrates 50 and 70 becomes easier and a highly reliable electronic device can be manufactured with a high efficiency.

Variants

The present invention, which is not limited to the above embodiment, can be modified variously. Now, variants of the semiconductor device according to the embodiment of the present invention will now be described. In addition, for the variants below, the descriptions given above will be applied as far as possible.

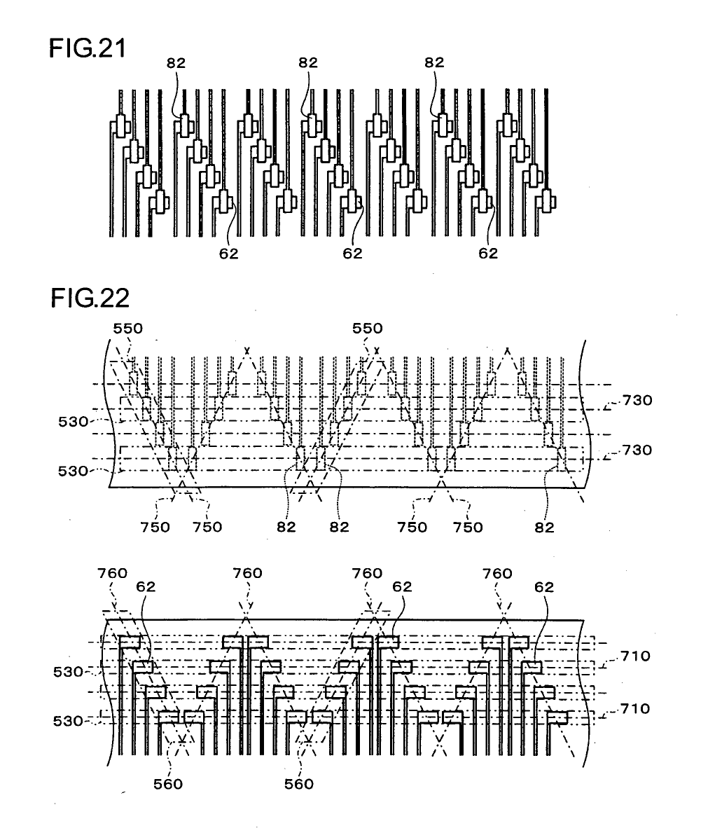

In a variant shown in FIG. 20 and FIG. 21, the plurality of second lands 82 are aligned so as to be divided into a plurality of third groups 545 that are placed along a plurality of third lines 745 stretching in a direction crossing the second line 730 (refer to FIG. 20). The plurality of third lines 745 stretch in a direction oblique to the second line 730. Further, the plurality of third lines 745 stretch respectively in parallel. Here, the first lands 62 can be aligned so as to be divided into a plurality of fourth groups 525 that are placed respectively along a plurality of fourth lines 725 stretching in a direction crossing the first line 710, and the plurality of fourth lines 725 can stretch respectively in parallel. In addition, as shown in FIG. 21, the first and the second lands 62 and 82 are electrically connected to each other by being overlapped so that they may cross lengthwise.

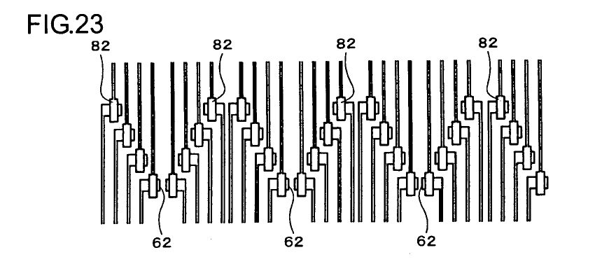

In a variant shown in FIG. 22 and FIG. 23, the second lands 82 can be aligned so as to be divided into a plurality of third groups 550 that are placed respectively along a plurality of third lines 750 stretching in a direction crossing the second line 730. The third line 750 can stretch in a direction oblique to the second line 730, and adjacent two of the third lines 750 are in linear symmetry with a line perpendicular to the second line 730 as an axis of symmetry. Here, the first lands 62 can be aligned so as to be divided into a plurality of fourth groups 560 that are placed respectively along a plurality of fourth lines 760. Adjacent two of the fourth lines 760 can be in linear symmetry with a line perpendicular to the first line 710 as an axis of symmetry. Further, as shown in FIG. 23, the first and the second lands 62 and 82 are electrically connected to each other by being overlapped so that they may cross lengthwise.

With the above variants, an effect equivalent to that of the above embodiment can be achieved. In addition, for other configurations, any of the description given above can be applied.

In addition, the present invention is not limited to the above embodiments and can be modified variously. For example, the present invention comprises a configuration that is virtually the same as the configurations described in the above embodiments (for example, a configuration having the same function, method and result, or a configuration having the same purpose and effect). Also, the present invention comprises configurations wherein part of the configurations described in the above embodiments, excluding their essence, is modified. Further, the present invention comprises configurations that can bring the same effect or achieve the same purpose as those of the configurations described in the above embodiments. In addition, the present invention comprises configurations wherein a publicly known technique is added to the configurations described in the above embodiments.

1. A semiconductor device, comprising:
a substrate having a wiring pattern including a plurality of lands; and
a semiconductor chip having a plurality of electrodes that are mounted on the substrate so that the electrodes are placed opposite to the lands, wherein:
the plurality of lands are aligned so as to be divided into a plurality of first groups that are placed respectively along a plurality of first parallel lines, and form a contour spreading along the first line;
the wiring pattern includes a plurality of wires that are drawn out from the plurality of lands and respectively stretch in a direction crossing the first line;
the plurality of electrodes are aligned so as to be divided into a plurality of second groups each of that is placed along each of a plurality of second parallel lines respectively, and form a contour spreading in a direction crossing the second line; and
each of the plurality of lands is overlapped with each of the plurality of electrodes respectively, crossing lengthwise, so as to be electrically connected.

2. The semiconductor device according to claim 1, wherein the plurality of electrodes are aligned so as to be divided into a plurality of third groups each of that is placed along each of a plurality of third lines respectively stretching in a direction crossing the second line.

3. The semiconductor device according to claim 2, wherein the third line stretches in a direction orthogonal to the second line.

4. The semiconductor device according to claim 2, wherein the third line stretches in a direction oblique to the second line.

5. The semiconductor device according to claim 4, wherein adjacent two of the third lines stretch in parallel.

6. The semiconductor device according to claim 4, wherein adjacent two of the third lines are in linear symmetry with a line perpendicular to the second line as an axis of symmetry.

7. The semiconductor device according to claim 2, wherein the plurality of lands are aligned so as to be divided into a plurality of fourth groups that are placed respectively along a plurality of fourth lines stretching in a direction crossing the first line.

8. The semiconductor device according to claim 7, wherein a group of the wires that are drawn out respectively from the lands of a same fourth group are drawn out from a same side of two sides, of the lands of the same forth group, along the first line.

9. The semiconductor device according to claim 8, wherein the lands of the same fourth group protrude, with different lengths, on the same side of two sides along the first line, and the protrusions are formed so that the length of the protrusions becomes longer in an order aligned along any of the fourth lines.

10. The semiconductor device according to claim 9, wherein the first group of wires each of that is drawn out from each of the lands of the same fourth group respectively, are configured so that, next to one of the wires connected to one of the lands, a first land, and at the same time on the side where the first land is protruding, another one of the wires connected to another one of the lands, a second land, that has a protrusion length next longest to that of the first land is configured.

11. An electronic device, comprising:
a first substrate having a first wiring pattern including a plurality of first lands; and
a second substrate having a second wiring pattern including a plurality of second lands, wherein:
the plurality of first lands are aligned so as to be divided into a plurality of first groups each of that is placed along each of a plurality of first lines respectively, and form a contour spreading in a direction along the first line;
the first wiring pattern includes first wires that are drawn out from the plurality of first lands and respectively stretch in a direction crossing the first line;
the plurality of second lands are aligned so as to be divided into a plurality of second groups each of that are placed along each of a plurality of second parallel lines respectively, and form a contour spreading in a direction crossing the second line;
the second wiring pattern includes second wires each of that is drawn out from the plurality of second lands and stretch in each of directions crossing the second line respectively; and
the plurality of first lands and the plurality of second lands are placed opposite to each other, crossing lengthwise, so as to be electrically connected.

12. The electronic device according to claim 11, wherein the plurality of second lands are aligned so as to be divided into a plurality of third groups each of that is placed along each of a plurality of third lines stretching in a direction crossing the second line respectively.

13. The electronic device according to claim 12, wherein the third line stretches in a direction oblique to the second line.

14. The electronic device according to claim 13, wherein adjacent two of the third lines stretch in parallel.

15. The electronic device according to claim 13, wherein adjacent two of the third lines are in linear symmetry with a line perpendicular to the second line as an axis of symmetry.

16. The electronic device according to claim 12, wherein the plurality of first lands are aligned so as to be divided into a plurality of fourth groups each of that is placed along each of a plurality of fourth lines stretching in a direction crossing the first line respectively.

17. The electronic device according to claim 16, wherein a group of the first wires each of that is drawn out from each of the first lands of a same fourth group respectively, are drawn out from a same side of two sides, of the first lands of the same forth group, along the first line.

18. A method for manufacturing a semiconductor device, comprising:
mounting a semiconductor chip, having a plurality of electrodes, on a substrate, having a wiring pattern including a plurality of lands, so that the electrodes and the lands is placed opposite to each other, for the purpose of electrically connecting the electrodes and the lands;
aligning the plurality of lands so as to be divided into a plurality of first groups each of that is placed along each of a plurality of first parallel lines respectively, and form a contour stretching along the first line;
configuring the wiring pattern including a plurality of wires each of that is drawn out from the plurality of lands and stretch in each of directions crossing the first line respectively;
aligning the plurality of electrodes so as to be divided into a plurality of second groups each of that is placed along each of a plurality of second parallel lines respectively, and form a contour spreading in a direction crossing the second line; and
overlapping the plurality of lands and the plurality of electrodes so as to cross each other lengthwise.

19. The method for manufacturing a semiconductor device according to claim 18, wherein the plurality of electrodes are aligned so as to be divided into a plurality of third groups each of that is placed along each of a plurality of third lines stretching in a direction crossing the second line respectively.

20. The method for manufacturing a semiconductor device according to claim 19, wherein the third line stretch in a direction orthogonal to the second line.

21. The method for manufacturing a semiconductor device according to claim 19, wherein the third line stretch in a direction oblique to the second line.

22. The method for manufacturing a semiconductor device according to claim 21, wherein adjacent two of the third lines stretch in parallel.

23. The method for manufacturing a semiconductor device according to claim 21, wherein adjacent two of the third lines are in linear symmetry with a line perpendicular to the second line as an axis of symmetry.

24. The method for manufacturing a semiconductor device according to claim 19, wherein the plurality of lands are aligned so as to be divided into a plurality of fourth groups that are placed respectively along a plurality of fourth lines stretching in a direction crossing the first line.

25. The method for manufacturing a semiconductor device according to claim 24, wherein a group of the wires that are drawn out respectively from the lands of a same fourth group are drawn out from a same side of two sides, of the lands of the same forth group, along the first line.

26. The method for manufacturing a semiconductor device according to claim 25, wherein the lands of the same fourth group protrude, with different lengths, on a same side of two sides along the first line, and the protrusions are formed so that the protrusion's length becomes longer in an order aligned along any of the fourth lines.

27. The method for manufacturing a semiconductor device according to claim 26, wherein the group of wires each of that is drawn out from each of the lands of the same fourth group respectively, are configured so that, next to one of the wires connected to one of the lands, a first land, and at the same time on the side where the first land is protruding, another one of the wires connected to another one of the lands, a second land, that has a protrusion length next longest to that of the first land is configured.

28. A method for manufacturing an electronic device, comprising the steps of:
placing a plurality of first lands of a first wiring pattern, provided on a first substrate, opposite to a plurality of second lands of a second wiring pattern, provided on a second substrate, for the purpose of electrically connecting them;
aligning the plurality of first lands so as to be divided into a plurality of first groups each of that is placed along each of a plurality of first parallel lines respectively, and form a contour spreading along the first line;
configuring the first wiring pattern including first wires each of that is drawn out from each of the plurality of first lands and stretch in each of directions crossing the first line respectively;
aligning the plurality of second lands so as to be divided into a plurality of second groups each of that is placed along each of a plurality of second parallel lines respectively, and forming a contour spreading in a direction crossing the second line;
configuring the second wiring pattern including second wires that are drawn out from the plurality of second lands and stretch respectively in a direction crossing the second line; and
overlapping the plurality of first lands and the plurality of second lands so as to cross each other lengthwise.

29. The method for manufacturing an electronic device according to claim 28, wherein the plurality of second lands are aligned so as to be divided into a plurality of third groups each of that is placed along each of plurality of third lines stretching in a direction crossing the second line respectively.

30. The method for manufacturing an electronic device according to claim 29, wherein the third line stretch in a direction oblique to the second line.

31. The method for manufacturing an electronic device according to claim 30, wherein adjacent two of the third lines stretch in parallel.

32. The method for manufacturing an electronic device according to claim 30, wherein adjacent two of the third lines are in linear symmetry with a line perpendicular to the second line as an axis of symmetry.

33. The method for manufacturing an electronic device according to claim 29, wherein the plurality of first lands are aligned so as to be divided into a plurality of fourth groups that are placed respectively along a plurality of fourth lines stretching in a direction crossing the first line.

34. The method for manufacturing an electronic device according to claim 33, wherein a group of the first wires each of that is drawn out from each of the first lands of a same fourth group respectively, are drawn out from a same side of two sides, of the first lands of the same forth group, along the first line.
